(19) United States
(12) Patent Application Publication
(10) Pub. No.: US 2008/0272828 A1
(43) Pub. Date: Nov. 6, 2008

(54) Method and system for adaptive power management

(75) Inventor: Sung-Ki Min, Cupertino, CA (US)

Correspondence Address: BAKER BOTTS L.L.P., 2001 ROSS AVENUE, SUITE 600, DALLAS, TX, 75201-2980, US

(73) Assignee: DSM SOLUTIONS, INC.

(21) Appl. No.: 12/113,323

(22) Filed: May 1, 2008

Related U.S. Application Data
(60) Provisional application No. 60/915,850, filed on May 3, 2007.

(51) Int. Cl. H01L 37/00

(52) U.S. Cl. 327/512

(57) ABSTRACT

A system comprises an integrated circuit comprising one or more transistors that receive a supply voltage. The system also includes a reference transistor operable to receive a constant current and produce a reference voltage that varies according to temperature or process variations, wherein the reference transistor behaves similarly to at least one of the one or more transistors with respect to temperature or process variations. The system also includes a comparator operable to compare the reference voltage with the received supply voltage and produce an output based at least in part on the difference between the reference voltage and the received supply voltage. The system further includes a controller operable to adjust the received supply voltage based at least in part on the output of the comparator.

### RELATED APPLICATIONS

This application claims the benefit under 35 U.S.C. § 119(e) of U.S. Provisional Patent Application Ser. No. 60/915,850 filed on May 3, 2007.

### TECHNICAL FIELD

This disclosure relates in general to electronic circuits and more particularly to a method and system for adaptive power management for integrated circuits, including enhancement JFET integrated circuits.

### OVERVIEW

As a result of the rapid technological growth of the past several decades, transistors and other semiconductor devices have become a fundamental building block for a wide range of electronic components. One or more operating characteristics of a transistor may be affected by temperature changes and process variations. In some applications, transistors may exhibit inconsistent performance across the range of operating temperatures and process variations. Such inconsistent performance can lead to excess power consumption and/or other operational inefficiencies.

Advanced transistor devices can have a large positive temperature coefficient with respect to drive current. This may be a disadvantage in high performance chip design with a fixed supply voltage scheme. The lowest performance may happen in the lowest temperature when the drive current is the lowest. If a higher supply voltage is used, like 0.55 V instead of 0.5 V, the performance may be improved in low temperature. But at high temperature this can unnecessarily waste power and potentially cause thermal problems. In enhancement mode junction field effect transistor (JFET) technology, the gate pn-junction diode will be more strongly forward biased due to the negative temperature coefficient (˜−2 mV per degree Celsius), which can cause gate leakage problems.

With an adaptive supply voltage scheme, the above problem can be resolved. Furthermore, the “large” and “positive” temperature coefficient can be turned into an advantage in advanced transistor circuit designs. The supply voltage may be adaptively adjusted using temperature sensing. At high chip temperature, the supply voltage can be lowered. At low chip temperature, the supply voltage can be raised so that the drive current can be kept relatively constant across a range of temperatures. Because the supply voltage can be lower for a given performance target at higher temperature, the power dissipation at higher temperature is lower, resulting in advantages in thermal design of the chip and packaging.

### SUMMARY OF EXAMPLE EMBODIMENTS

In accordance with one embodiment of the present disclosure, a system comprises an integrated circuit comprising one or more transistors that receive a supply voltage. The system also includes a reference transistor operable to receive a constant current and produce a reference voltage that varies according to temperature and process variations, wherein the reference transistor behaves similarly to at least one of the one or more transistors with respect to temperature or process variations. The system also includes a comparator operable to compare the reference voltage with the received supply voltage and produce an output based at least in part on the difference between the reference voltage and the received supply voltage. The system further includes a controller operable to adjust the received supply voltage based at least in part on the output of the comparator.

In accordance with another embodiment of the present disclosure, a method includes providing a constant current to a reference transistor. The method also includes comparing a voltage associated with the reference transistor to a supply voltage of an integrated circuit, wherein the voltage associated with the reference transistor increases when a temperature associated with the reference transistor decreases and decreases when a temperature associated with the reference transistor increases, and wherein the voltage associated with the reference transistor varies according to temperature at a rate of approximately minus 2 millivolts per degree Celsius. The method further includes adjusting the supply voltage in response to a change in the voltage associated with the reference transistor.

Numerous technical advantages are provided according to various embodiments of the present disclosure. Particular embodiments of the disclosure may exhibit none, some, or all of the following advantages depending on the implementation. In certain embodiments, substantially consistent performance can be maintained for one or more transistors across a wide range of temperatures. In certain other embodiments, on-chip structures may be used to measure temperature. In some embodiments, power dissipation may be decreased.

Other technical advantages of the present disclosure will be readily apparent to one skilled in the art from the following figures, descriptions, and claims. Moreover, while specific advantages have been enumerated above, various embodiments may include all, some, or none of the enumerated advantages.

### BRIEF DESCRIPTION OF THE DRAWINGS

For a more complete understanding of the present disclosure and its advantages, reference is now made to the following description, taken in conjunction with the accompanying drawings, in which:

FIG. 1 illustrates a block diagram of an example system for adaptive power management;

FIG. 2 illustrates current and voltage characteristics of a pn-junction at different temperatures;

FIG. 3 illustrates an example JFET device that may be used in a digital logic circuit;

FIG. 4 illustrates one example embodiment of a temperature-sensing device for use in an adaptive power management system;

FIG. 5 illustrates an example power management system; and

FIG. 6 is a flowchart illustrating one example method for adaptive power management.

### DETAILED DESCRIPTION

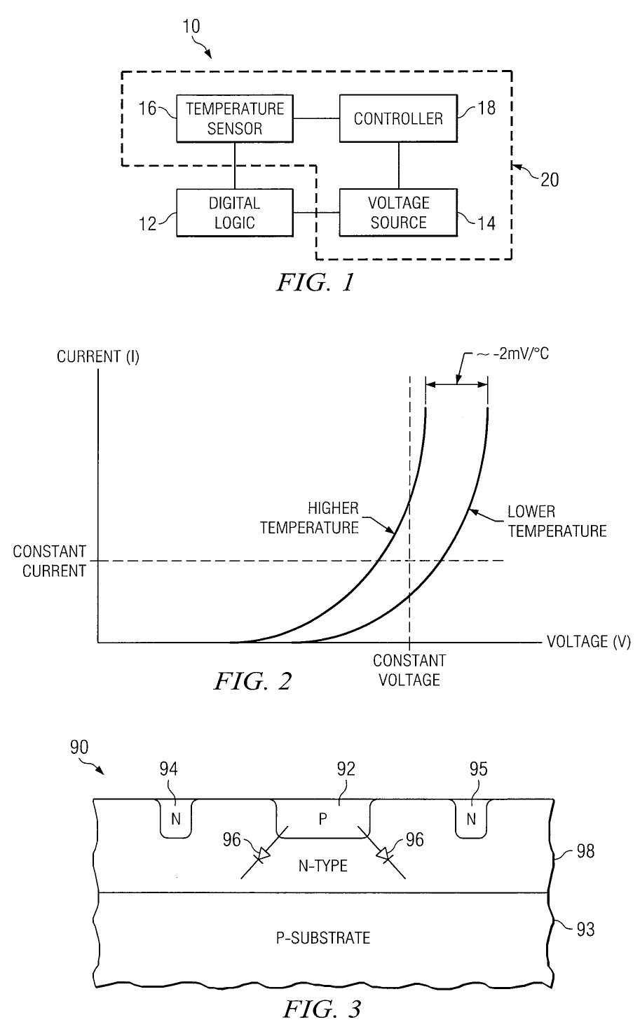

FIG. 1 illustrates a block diagram of an example system 10 for adaptive power management. The components of system 10 may be situated or connected in any suitable arrangement. In certain digital logic circuits, one or more advanced transistor devices may have a positive temperature coefficient. Lower performance may occur at lower temperatures, and higher performance may occur at higher temperatures. Adaptive power management system 10 may be used to sense a temperature associated with at least one of the one or more devices and adaptively adjust a voltage supply to maintain a consistent performance across a range of temperatures. At high chip temperature the supply voltage can be lowered, and at low chip temperature the supply voltage can be raised. System 10 comprises digital logic 12, voltage source 14, temperature sensor 16, controller 18, and feedback loop 20.

Digital logic 12 can be located in an integrated circuit or in any suitable location. Digital logic 12 may comprise one or more transistors or other semiconductor components operable to perform one or more functions. In certain embodiments, digital logic 12 can be comprised of one or more junction field effect transistors (JFETs). Some JFETs may have low operating voltages and low threshold voltages. In some embodiments, operating voltages can be 0.5 volts or lower.

A system can be used to increase or decrease the supply voltage as the temperature changes or process variations occur to ensure a consistent performance of the transistor across a wide range of temperatures or process variations. An adaptive power management system, like system 10, may be used to decrease the supply voltage as the temperature at or near digital logic 12 increases, and increase the supply voltage as the temperature at or near digital logic 12 decreases. This system can also lead to reduced power consumption while maintaining consistent performance, such as consistent operating speeds and drive current across a range of temperatures. On-chip structures may be used to read the temperature near digital logic 12.

Voltage source 14 comprises any suitable circuitry operable to provide one or more voltages to digital logic 12. In certain embodiments, voltage source 14 can provide a voltage of approximately 0.3 to 0.7 volts to digital logic 12 to power one or more transistors or other semiconductor components. In some embodiments, voltage source 14 provides a voltage to a gate terminal of one or more transistors within digital logic 12, such as in enhancement mode JFETs. In certain other embodiments, voltage source 14 may provide a voltage to digital logic 12, and suitable circuitry within digital logic 12 may convert that voltage to a higher and/or lower voltage for use within digital logic 12.

Temperature sensor 16 comprises any suitable component or set of components operable to detect, sense, or otherwise respond to one or more temperature changes in or near digital logic 12. In some embodiments, temperature sensor 16 may comprise an on-chip semiconductor structure, such as a transistor or diode used for sensing purposes. For example, temperature sensor 16 may comprise a diode that reacts to temperature changes. The voltage across a pn-junction of a diode may change with temperature changes, and this voltage can be used in a feedback loop, such as feedback loop 20, to adjust the voltage supplied by voltage source 14. Temperature sensor 16 could also comprise a reference transistor that responds to a change in temperature. The response of the reference transistor may be sensed and used to adjust the voltage supplied by voltage source 14. In certain embodiments, the reference transistor may be identical to at least one of the transistors in digital logic 12. In certain embodiments, the reference transistor may comprise an enhancement mode JFET that operates with an operating voltage of approximately 0.5 volts.

Controller 18 comprises any suitable combination of hardware, software, and firmware that adjusts the voltage provided by voltage source 14. Controller 18 may adjust voltage source 14 in response to one or more signals from temperature sensor 16. In certain embodiments, controller 18 can comprise a part of a feedback loop.

Feedback loop 20 comprises temperature sensor 16, controller 18, and voltage source 14. Feedback loop 20 may be used to measure and then adjust one or more voltages associated with digital logic 12 when the temperature changes. Feedback loop 20 may adjust a voltage in real time or periodically at set intervals.

System 10 may also compensate for process or voltage variations in certain embodiments. For example, a voltage provided by voltage source 14 may fluctuate slightly due to device imperfections or limitations. These fluctuations could, in turn, raise or lower the temperature of one or more devices within digital logic 12. Temperature sensor 16 could detect these temperature changes and controller 18 could use that information to alter the voltage provided by voltage source 14. System 10 can thus compensate for fluctuations or variations in voltage source 14.

System 10 may also, in certain embodiments, compensate for process variations within one or more semiconductor devices. Process variations may cause one or more characteristics of a semiconductor device to vary from one device to another, such as a voltage threshold. System 10 may employ a sensor comprised of one or more semiconductor devices that are similar to the devices within digital logic 12, which can be used to reduce the effect of process variations.

FIG. 2 illustrates the current and voltage characteristics of a pn-junction of a low-power JFET device at two example temperatures. The pn-junction diode voltage decreases by approximately 2 mV/° C. when the current is constant in certain embodiments. Constant current is represented on the graph by a horizontal line. As shown on the graph, at a higher temperature the current/voltage curve moves to the left, resulting in a lower voltage if the current is constant. With a constant current, at a higher temperature the voltage will be lower. This voltage can be monitored and used for thermal management.

FIG. 3 illustrates an example JFET device 90 that may be used in a digital logic circuit. JFET device 90 is not to scale and may comprise other structures and still fall within the scope of this disclosure. Device 90 comprises a p-type substrate 93 and an n-type channel 98, source 94, drain 95, gate 92, and pn-junction diodes 96. When the current of pn-junction diode 96 is used for control, forward biasing of the diode can be prevented. In certain low-voltage technologies, such as enhancement mode JFET technologies, strong forward biasing of the pn-junction between gate 92 and source 94 (or between a back gate and source 94) can make the devices non-operating. Controlling the current through pn-junction diode 96 can prevent this. At the same time, the speed difference between hot and cold temperature operation can become smaller.

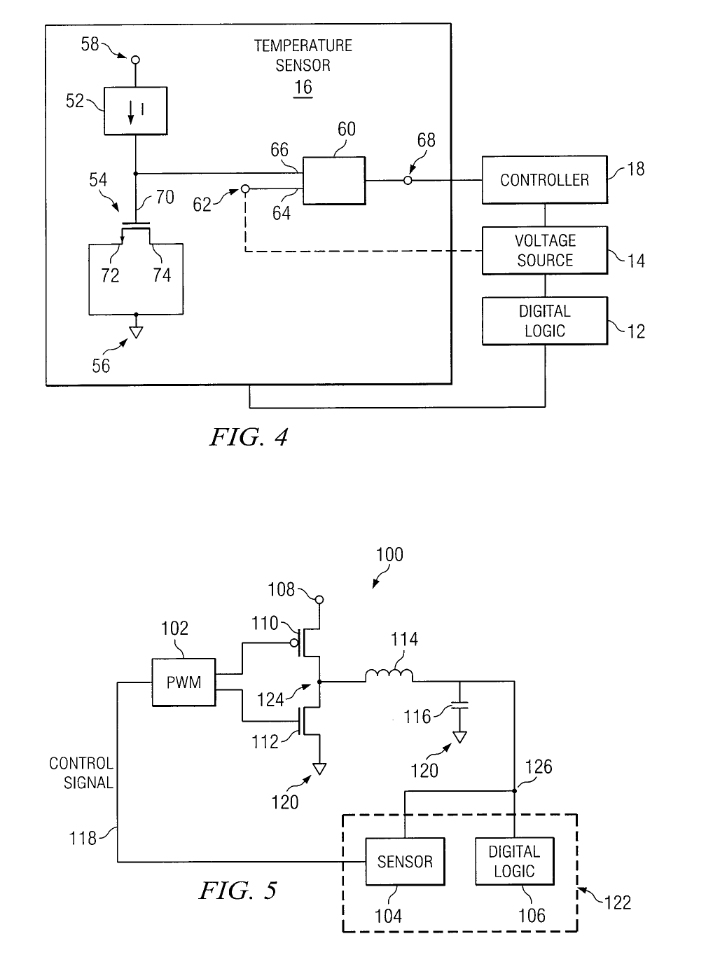

FIG. 4 illustrates one example embodiment of temperature-sensor 16 for use in adaptive power management system 10. Sensor 16 may comprise any component or number of components operable to measure a temperature at or near one or more semiconductor devices. In certain embodiments, multiple sensors may be implemented to have different optimal supply voltages at different specific locations on a chip.

Sensor 16 comprises reference transistor 54. In this embodiment, reference transistor 54 comprises a source terminal 72 and a drain terminal 74 connected to a ground node 56. Reference transistor 54 also comprises a gate terminal 70 connected to a constant current source 52. Although not shown in FIG. 4, reference transistor 54 may also comprise a body terminal, which may be connected to ground. In the illustrated embodiment, reference transistor 54 is a p-type JFET. In certain embodiments, reference transistor 54 should be similar to at least one of the one or more transistors that comprise digital logic 12. If reference transistor 54 reacts similarly to temperature changes as the transistors in digital logic 12, then reference transistor 54 can be monitored and used as a part of feedback loop 20 to adjust voltage source 14. A voltage associated with reference transistor 54, such as the voltage across a gate pn-junction, may change as the temperature changes, and this change may be used in feedback loop 20 to modify voltage source 14 to compensate for the temperature changes.

Constant current source 52 operates to provide a constant current to gate terminal 70 of reference transistor 54. Constant current source 52 comprises any component or system of components operable to perform this function, such as a simple transistor current source. Constant current source 52 may be connected to one or more voltage nodes, such as node 58, which provides power to constant current source 52.

Sensor 16 may also comprise comparator 60. Comparator 60 may be used as part of a feedback loop (positive or negative) that adjusts voltage source 14 to compensate for one or more temperature changes. In this example embodiment, comparator 60 comprises input node 66, which receives as input the voltage at gate terminal 70 of reference transistor 54. Comparator 60 also comprises input node 64, which receives as input a supply voltage 62 used by one or more transistors in digital logic circuit 12. In certain embodiments, this supply voltage 62 is applied to a gate terminal of one or more JFETs within digital logic 12. Supply voltage 62 may be output from voltage source 14, as illustrated in FIG. 4, or may come from within digital logic 12. Comparator 60 compares supply voltage 62 to the voltage at gate terminal 70 of reference transistor 54 which is coupled to input node 66. Comparator 60 is operable to output a voltage to node 68 based at least in part on the difference between supply voltage 62 and the reference voltage at input node 66. The output voltage at node 68 changes depending on the difference between the voltages at the two comparator input nodes 64 and 66. The output voltage at node 68 can be fed to controller 18 and used in feedback loop 20 to alter the supply voltage 62 until the two comparator input voltages (at input nodes 64 and 66) fall within an acceptable range of one another.

Controller 18 may receive the output voltage at node 68 and adjust voltage source 14 either up or down based at least in part on the value of the voltage at node 68. In certain embodiments, this adjustment alters supply voltage 62 until it is approximately identical to the voltage at gate terminal 70 of reference transistor 54.

In operation, sensor 16 works as follows. Reference transistor 54 receives a constant current from constant current source 52. Reference transistor 54 comprises a pn-junction between its gate terminal and a channel of the transistor. Current from the constant current source 52 flows through this pn-junction and creates a voltage at the gate terminal. If the temperature at or near reference transistor 54 is constant, and the current from constant current source 52 is constant, then the voltage at gate terminal 70 of reference transistor 54 will also be relatively constant.

As the temperature increases, the pn-junction diode voltage of reference transistor 54 decreases at approximately 2 mV/° C. when the current is constant. This relationship can be used to alter voltage source 14 in response to one or more temperature changes. For example, when the pn-junction diode voltage decreases, comparator 60 receives this decreased voltage at input node 66. Supply voltage 62 will now be larger than the transistor reference voltage at node 66, and comparator 60 will output a voltage at node 68 based at least in part on this difference. The voltage at node 68 can then be used by other components, such as controller 18, to adaptively adjust voltage source 14 to decrease supply voltage 62 until it is approximately equal to the reference voltage at gate terminal 70 of reference transistor 54.

If the temperature decreases, the opposite effect occurs. The pn-junction diode voltage of reference transistor 54 increases and comparator 60 receives this increased voltage at input terminal 66. Comparator 60 and controller 18 can then act to raise supply voltage 62 until it is approximately equal to the reference voltage at gate terminal 70 of reference transistor 54.

Thus, as the temperature increases, the speed or drive current of one or more transistors in digital logic circuit 12 also increases. To prevent excessive power dissipation and to create more consistent speed and drive current across a range of temperatures, system 10 can be used to lower supply voltage 62, which may be used to operate one or more transistors in digital logic 12. This can be done to slow down the transistors as the temperature increases or reduce the drive current of the transistors, which can prevent damage to the transistors and also prevent forward biasing of the transistors. Also, since the transistors are operating with a lower supply voltage 62, power consumption may be reduced. In contrast, as the temperature decreases, the speed or drive current of the transistors may also decrease. In that situation, the present disclosure can be used to raise supply voltage 62 to increase the speed or drive current of the transistors to ensure consistent performance across a wide range of temperatures. In certain embodiments, a chip temperature range of −10° C. to 125° C. can lead to adaptive adjustments of up to 400 mV in the supply voltage. For example, a supply voltage may be adjusted to any value between 300 mV and 700 mV depending on temperature changes.

Sensor 16 also operates to keep the gate pn-junction voltage of transistors within digital logic 12 below a cut-in voltage. As temperature increases, the cut-in voltage is reduced, and there is a risk that the transistors may become forward biased. However, supply voltage 62 is reduced when the temperature increases, which decreases the risk that the transistors will become forward biased. Conversely, as the temperature decreases, the cut-in voltage is increased, and thus supply voltage 62 can be increased without the risk of forward biasing the transistors.

FIG. 5 illustrates an example power management system 100. The components of power management system 100 may be situated or connected in any suitable arrangement. System 100 generates a control signal 118 based at least in part on a temperature change to adjust a supply voltage. Power management system 100 comprises pulse width modulator (PWM) 102, sensor 104, digital logic 106, transistor 110 and 112, inductor 114, capacitor 116, and isothermal environment 122.

In power management system 100, sensor 104 can be used to detect a change in temperature near digital logic 106. Sensor 104 and digital logic 106 exist in isothermal environmental 122, which means that the temperature at sensor 104 is at or near the temperature of digital logic 106. Because they are near the same temperature, the temperature changes detected by sensor 104 may be used to adjust the voltage at node 126 supplied to digital logic 106.

When a change in temperature is detected by sensor 104, control signal 118 is sent to PWM 102. PWM 102 uses control signal 118 to determine how to adjust the voltage supplied to digital logic 106. PWM 102 can output one or more signals based at least in part on control signal 118. The signals output by PWM 102 may be used to selectively turn transistors 110 and 112 on and off to produce an appropriate voltage at node 124. Transistor 110 is coupled to external voltage supply 108 and node 124. Transistor 112 is coupled to node 124 and ground node 120.

The voltage produced at node 124 can be filtered by inductor 114 and capacitor 116. This L-C filter may be used to reduce the voltage ripple at node 126. Thus, PWM 102 uses control signal 118 to determine whether the voltage supplied to digital logic 106 at node 126 should be adjusted up or down. The output of PWM 102 creates an appropriate voltage at node 124, and this voltage is filtered and then sent to node 126, where it can be used by digital logic 106. By this process, power management system 100 is operable to adjust a supply voltage for digital logic 106 based at least in part on a temperature measured near digital logic 106 in order to maintain consistent performance across a range of temperatures.

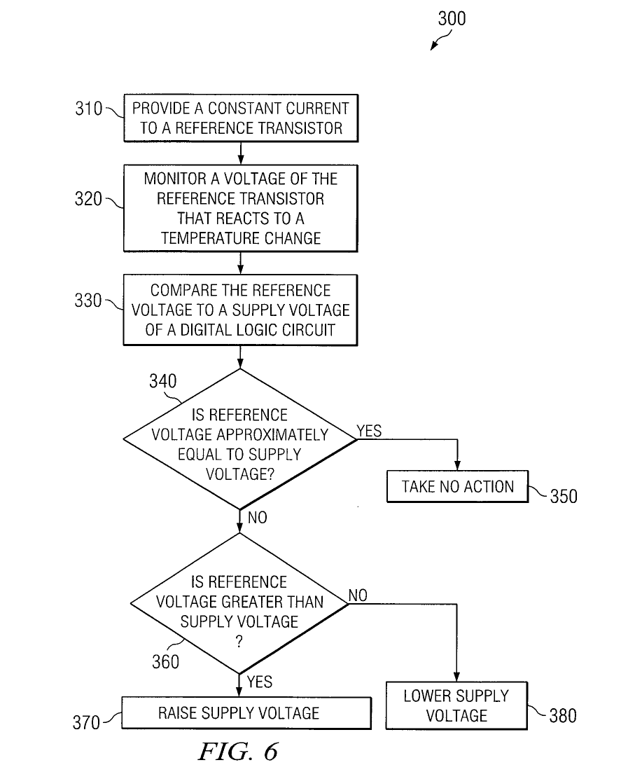

FIG. 6 is a flowchart illustrating one example method 300 for an adaptive power management system 10. In particular, the illustrated method can adjust a voltage source 14 in response to one or more temperature changes. The steps illustrated in FIG. 6 may be combined, modified, or deleted where appropriate. Additional steps may also be added to the example operation. Furthermore, the described steps may be performed in any suitable order.

The method begins with step 310. In step 310, a constant current is provided to reference transistor 54. In certain embodiments, reference transistor 54 is similar to at least one of one or more transistors within digital logic 12. Reference transistor 54 also comprises a voltage that adjusts to one or more temperature changes at approximately −2 mV/° C.

In step 320, a voltage of reference transistor 54 that reacts to a change in temperature is monitored. In certain embodiments, this voltage can be a voltage at a gate terminal 70 of reference transistor 54. The reference voltage can be monitored in a variety of ways. In some embodiments, a pn-junction voltage that changes with temperature may be monitored.

In step 330, the reference voltage of reference transistor 54 can be compared to supply voltage 62 for digital logic 12. A comparator 60 may be used that accepts as input the reference voltage of reference transistor 54 and supply voltage 62. Comparator 60 may output a value based at least in part on the difference between the reference voltage of reference transistor 54 and supply voltage 62. This value may be used in feedback loop 20 to adjust supply voltage 62.

In step 340, the reference voltage of reference transistor 54 and supply voltage 62 are compared to determine if they are approximately equal. If they are approximately equal, then no adjustment needs to be done, as illustrated in step 350. If the voltages are not approximately equal, then the method continues to step 360. “Approximately equal” in this case refers to the voltages being within a range of one another that is acceptable for the desired operation of the system. This range may vary depending on the details of digital logic 12 or any other circuit being monitored.

At step 360, the reference voltage of reference transistor 54 and supply voltage 62 are compared to determine which is greater. If the reference voltage is greater, the temperature of the circuit must have decreased, and supply voltage 62 can be increased in step 370 so that the speed and drive current of the transistors in digital logic 12 may also increase. This increase in supply voltage 62 can help to counter the effect of the decreased temperature, providing a more consistent performance for the transistors in digital logic 12 across a range of temperatures.

If the reference voltage of reference transistor 54 is lower than supply voltage 62, the temperature of the circuit must have increased, and supply voltage 62 can be decreased in step 380 to also decrease the speed and drive current of the transistors in digital logic 12. This can prevent excess power consumption by the transistors. It can also prevent forward biasing of one or more transistors in digital logic 12. It also may allow for more consistent performance of the transistors when the temperature increases.

The output of comparator 60 may be used as an input in feedback loop 20 that continually adjusts supply voltage 62 until it approximately matches the voltage of reference transistor 54. As the reference voltage of reference transistor 54 increases, supply voltage 62 can be increased. As the reference voltage of reference transistor 54 decreases, supply voltage 62 can be decreased. Steps 310-380 can be continually performed in a loop so that supply voltage 62 can be adaptively adjusted to any changes in temperature. The adjustments to supply voltage 62 can be made at any suitable time intervals.

Although the present disclosure has been described with several embodiments, a myriad of changes, variations, alterations, transformations, and modifications may be suggested to one skilled in the art, and it is intended that the present disclosure encompass such changes, variations, alterations, transformations, and modifications as fall within the scope of the appended claims.

What is claimed is:

1. A system, comprising:
an integrated circuit comprising one or more transistors that receive a supply voltage;
a reference transistor operable to receive a constant current and produce a reference voltage that varies according to temperature or process variations, wherein the reference transistor behaves similarly to at least one of the one or more transistors with respect to temperature or process variations;
a comparator operable to compare the reference voltage with the received supply voltage and produce an output based at least in part on the difference between the reference voltage and the received supply voltage; and
a controller operable to adjust the received supply voltage based at least in part on the output of the comparator.

2. The system of claim 1 wherein the reference voltage decreases at a rate of approximately 2 millivolts per degree Celsius.

3. The system of claim 1, wherein the reference transistor comprises an enhancement mode JFET.

4. The system of claim 3, wherein the reference transistor comprises a drain terminal and a source terminal coupled to a ground node.

5. The system of claim 1, wherein the reference transistor receives the constant current at a gate terminal.

6. The system of claim 1, wherein the supply voltage is between 0.3 and 0.7 volts.

7. The system of claim 1, wherein the supply voltage does not exceed a pn-j unction forward bias voltage of the one or more transistors.

8. The system of claim 1, wherein the controller lowers the supply voltage when the temperature of the reference transistor increases and raises the supply voltage when the temperature of the reference transistor decreases.

9. The system of claim 1, wherein the controller lowers the supply voltage when the cut-in voltage of the reference transistor is lower due to process variations and raises the supply voltage when the cut-in voltage of the reference transistor is higher due to process variations.

10. The system of claim 1, wherein the controller comprises a feedback loop that adjusts the supply voltage to approximately match the reference voltage.

11. The system of claim 1, wherein a gate terminal of the one or more transistors can receive a voltage level approximately equal to the supply voltage.

12. A method, comprising:
providing a constant current to a reference transistor;
comparing a voltage associated with the reference transistor to a supply voltage of an integrated circuit, wherein the voltage associated with the reference transistor increases when a temperature associated with the reference transistor decreases or when the cut-in voltage of the reference transistor is lower due to process variations, and wherein the voltage associated with the reference transistor decreases when a temperature associated with the reference transistor increases or when the cut-in voltage of the reference transistor is higher due to process variations, and wherein the voltage associated with the reference transistor decreases according to temperature at a rate of approximately 2 millivolts per degree Celsius; and
adjusting the supply voltage in response to a change in the voltage associated with the reference transistor.

13. The method of claim 12, wherein the reference transistor comprises a JFET.

14. The method of claim 12, wherein a feedback loop is used to adjust the supply voltage, and wherein the feedback loop comprises:
the reference transistor;
a comparator operable to compare the voltage associated with the reference transistor to the supply voltage; and
a controller operable to adjust the supply voltage in response to a change to the voltage associated with the reference transistor.

15. The method of claim 12, wherein the reference transistor comprises a JFET with a source terminal and a drain terminal coupled to a ground node.

16. The method of claim 12, wherein the supply voltage is between 0.3 and 0.7 volts.

17. The method of claim 12, wherein the integrated circuit comprises one or more transistors, and wherein at least one of the one or more transistors is of identical device structure to the reference transistor.

18. The method of claim 17, wherein a gate terminal of at least one of the one or more transistors in the integrated circuit can receive a voltage level approximately equal to the supply voltage.

19. The method of claim 12, wherein the voltage associated with the reference transistor comprises a voltage at a gate terminal of the reference transistor.

20. The method of claim 12, wherein comparing a voltage associated with the reference transistor to a supply voltage of an integrated circuit comprises producing a voltage output based at least in part on the difference between the voltage associated with the reference transistor and the supply voltage.

21. A system, comprising:
an integrated circuit comprising one or more JFETs that receive a supply voltage at a gate terminal, wherein the supply voltage is between 0.3 and 0.7 volts;
a reference JFET comprising a source terminal, drain terminal, and body tied to ground, the reference JFET operable to receive a constant current and produce a reference voltage at a gate terminal that varies according to temperature at a rate of approximately 2 millivolts per degree Celsius, wherein the reference voltage increases when the temperature decreases and decreases when the temperature increases;
wherein the reference voltage further varies as a function of process variations of the reference JFET;
a comparator operable to receive as inputs the reference voltage and the supply voltage, and operable to produce an output based at least in part on the difference between the reference voltage and the supply voltage; and
a controller operable to use the output of the comparator to adjust the supply voltage until it is approximately equal to the reference voltage.
